(19) United States
(12) Patent Application Publication
(10) Pub. No.: US 2006/0067535 A1
(43) Pub. Date: Mar. 30, 2006

(54) Method and system for automatically equalizing multiple loudspeakers

(76) Inventors: Michael Culbert, Monte Sereno, CA (US); Jon Rubinstein, San Francisco, CA (US); Aram Lindahl, Menlo Park, CA (US)

Correspondence Address: Nancy R. Simon;Simon & Koerner LLP, Suite B, 10052 Pasadena Avenue, Cupertino, CA, 95014, US

(21) Appl. No.: 10/951,666

(22) Filed: Sep. 27, 2004

(51) Int. Cl. H04R 29/00; H03G 3/00

(52) U.S. Cl. 381/58; 381/61; 381/103

(57) ABSTRACT

A computing device generates an audio signal that includes a pattern and transmits the audio signal to the loudspeakers. A measuring device located at a listening position sequentially captures the signal and pattern reproduced by the speakers. The measuring device transmits each captured signal and pattern to the computing device. The computing device determines the frequency and impulse responses for each loudspeaker and equalizes the speakers for the listening position. Some or all of the speakers may be associated with additional listening positions. The computing device may then equalize the speakers based on each listening position. Alternatively, the computing device may calculate an average for some or all of the listening positions and equalize the speakers based on the average.

### BACKGROUND

Loudspeakers can significantly enhance the listening experience for a user. Unfortunately, installing loudspeakers in a room can be difficult. The placement of the speakers and their characteristics,. such as phase and frequency responses, make setting up and balancing the speakers challenging.

FIG. 1 is a graph of a frequency response of a loudspeaker in a room according to the prior art. Due to sound reflecting off the walls, ceiling, floor, and objects in the room, response 100 varies considerably over frequency. The variations in response 100 can degrade the quality of the sound a user experiences in a room.

Moreover, at frequency f₁, the reflections create a mode 102, which occurs when the standing waves of the reflections are added together. At frequency f₂, the reflections create a null 104, which occurs when the standing waves of the reflections cancel each other. Mode 102 and null 104 are not easily eliminated from a room.

The phase responses of the speakers also affect the sound quality in a room. FIG. 2 is a graph of an impulse response of two loudspeakers in a room according to the prior art. Response 200 occurs at time t₁, while response 202 at time t₂. When the two waveforms are separated in time, or partially overlap, the quality of the sound in the room is diminished.

### SUMMARY

In accordance with the invention, a method and system for automatically equalizing multiple loudspeakers are provided. A computing device generates an audio signal that includes a pattern and transmits the audio signal to the loudspeakers. A measuring device located at a listening position sequentially captures the signal and pattern reproduced by the speakers. The measuring device transmits each captured signal and pattern to the computing device. The computing device determines the frequency and impulse responses for each loudspeaker and equalizes the speakers for the listening position. Some or all of the speakers may be associated with additional listening positions. The computing device may then equalize the speakers based on each listening position. Alternatively, the computing device may calculate an average for some or all of the listening positions and equalize the speakers based on the average.

### BRIEF DESCRIPTION OF THE DRAWINGS

The invention will best be understood by reference to the following detailed description of embodiments in accordance with the invention when read in conjunction with the accompanying drawings, wherein:

FIG. 1 is a graph of a frequency response of a loudspeaker in a room according to the prior art;

FIG. 2 is a graph of an impulse response of two loudspeakers in a room according to the prior art;

FIG. 3 is a block diagram of a first system for equalizing multiple loudspeakers in an embodiment in accordance with the invention;

FIG. 4 is a block diagram of a second system for equalizing multiple loudspeakers in an embodiment in accordance with the invention;

FIG. 5 is a block diagram of a system for synchronizing time in an embodiment in accordance with the invention;

FIGS. 6A-6B illustrate a flowchart of a method for automatically equalizing multiple loudspeakers in an embodiment in accordance with the invention;

FIG. 7 depicts a flowchart of a method for applying an offset for the frequency response of a loudspeaker in an embodiment in accordance with the invention;

FIG. 8 is a block diagram of a system for applying an offset for the frequency response in accordance with FIG. 7;

FIG. 9 illustrates a flowchart of a method for applying an offset for the impulse response of a loudspeaker in an embodiment in accordance with the invention;

FIG. 10 is a block diagram of a loudspeaker for applying an offset for the impulse response in accordance with FIG. 9; and

FIG. 11 depicts a flowchart of a method for audio playback in an embodiment in accordance with the invention.

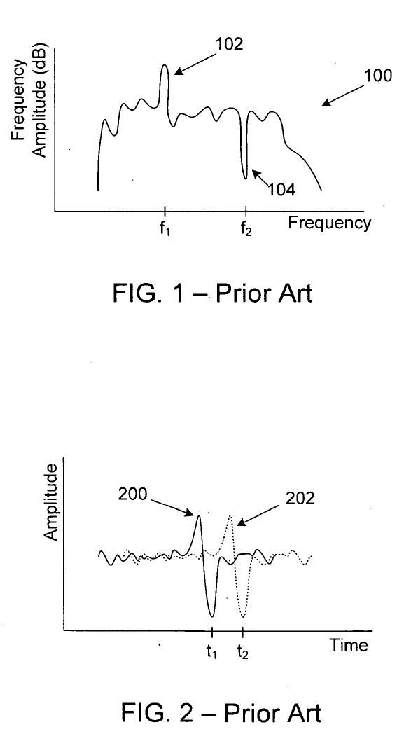

### DETAILED DESCRIPTION

The following description is presented to enable one skilled in the art to make and use embodiments of the invention, and is provided in the context of a patent application and its requirements. Various modifications to the disclosed embodiments will be readily apparent to those skilled in the art, and the generic principles herein may be applied to other embodiments. Thus, the invention is not intended to be limited to the embodiments shown, but is to be accorded the widest scope consistent with the appended claims and with the principles and features described herein.

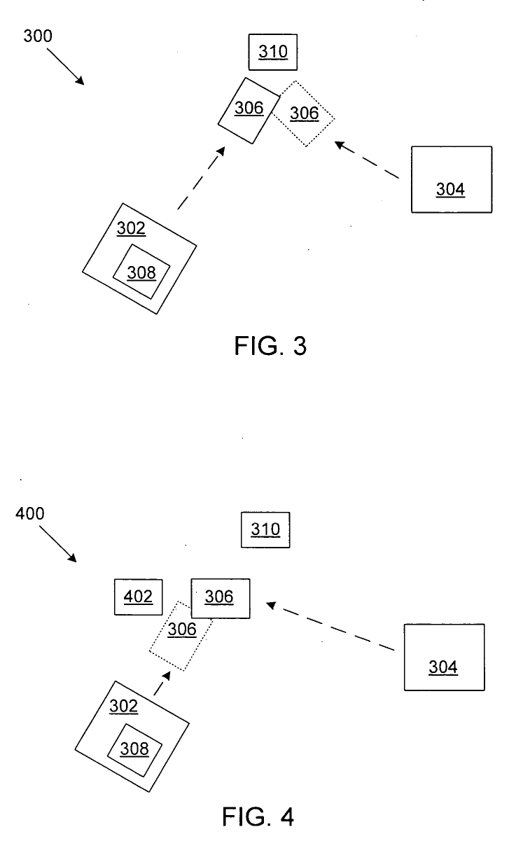

With reference to the figures and in particular with reference to FIG. 3, there is shown a block diagram of a first system for equalizing multiple loudspeakers in an embodiment in accordance with the invention. System 300 includes speakers 302, 304, measurement device 306, and computing device 308. In one embodiment in accordance with the invention, computing device is implemented as a computer located in the interior of speaker 302. In another embodiment in accordance with the invention, computing device 308 may be situated outside of speaker 302. And in yet another embodiment in accordance with the invention, computing device may be implemented as another type of computing device.

Measurement device 306 is implemented as any device that captures sound and transmits the sound to computing device 308. In one embodiment in accordance with the invention, measurement device 306 is a wireless microphone. Measurement device 306 successively captures the sound emitted from speakers 302, 304 and transmits the sound to computing device 308.

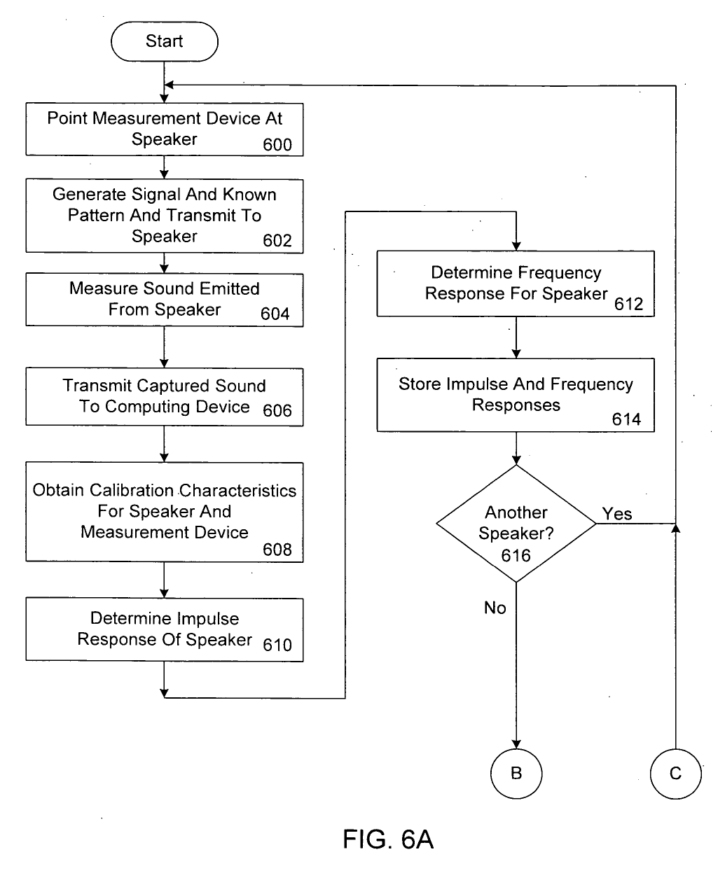

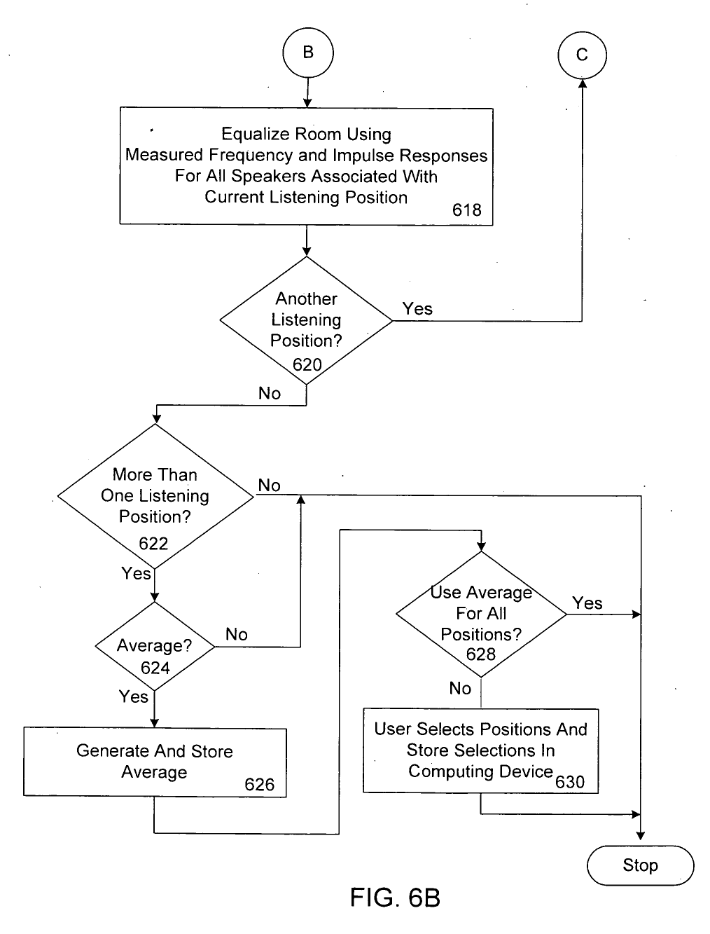

A user selects a listening position 310 and points measurement device 306 towards speaker 302. After sampling the sound emitted from speaker 302, measurement device 306 transmits the sampled sound to computing device 308. The user then repositions measurement device 306 so that measurement device 306 points toward speaker 304. Measurement device 306 captures the sound emitted from speaker 304 and transmits the sampled sound to computing device 308. After receiving the sound captured from speakers 302, 304, computing device 308 automatically generates compensation or offset values that equalize speakers 302, 304 for listening position 310. The process of equalizing the speakers is described in more detail in conjunction with FIGS. 6-10.

FIG. 4 is a block diagram of a second system for equalizing multiple loudspeakers in an embodiment in accordance with the invention. System 400 includes speakers 302, 304, measurement device 306, and computing device 308. After equalizing the sound for listening position 310, the user places measurement device 306 at listening position 402 and directs measurement device 306 towards speaker 304. After sampling the sound emitted from speaker 304, measurement device transmits the sampled sound to computing device 308. The user then repositions measurement device 306 so that measurement device 306 points toward speaker 302. Measurement device 306 then captures the sound emitted from speaker 302 and transmits the sampled sound to computing device 308. After receiving the sound captured from speakers 302, 304, computing device 308 automatically generates compensation or offset values that equalize speakers 302, 304 for listening position 402. The process of equalizing the speakers is described in more detail in conjunction with FIGS. 6-10.

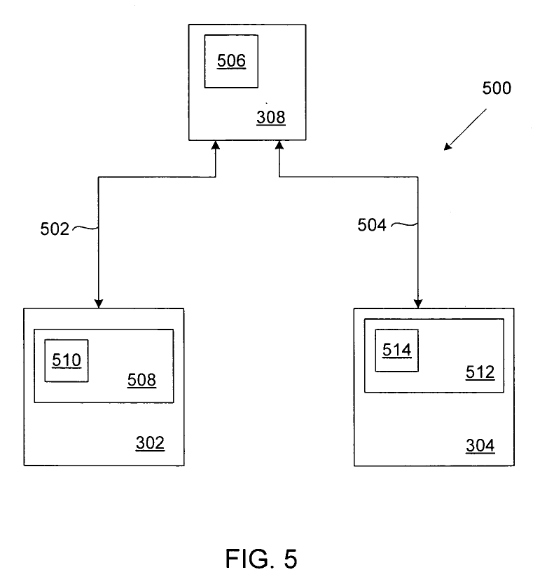

Referring now to FIG. 5, there is shown a block diagram of a system for synchronizing time in an embodiment in accordance with the invention. System 500 includes computing device 308 and loudspeakers 302, 304. Although system 500 is shown with two loudspeakers, embodiments in accordance with the invention can include any number of speakers. Time is synchronized for all of the speakers associated with the computing device, and the speakers may be located in the same room or in separate rooms.

Communications between computing device 308 and speakers 302, 304 occur over connections 502, 504, respectively. Connections 502, 504 are wireless connections in an embodiment in accordance with the invention. Connections 502, 504 may be wired connections in other embodiments in accordance with the invention.

Computing device 308 includes clock 506. Loudspeaker 302 includes network system 508 and clock 510. And loudspeaker 304 includes network system 512 and clock 514. Computing device 308 acts as a time server and synchronizes clocks 510, 514 to clock 506. In one embodiment in accordance with the invention, computing device 308 synchronizes time using Network Time Protocol (NTP). In other embodiments in accordance with the invention, computing device 308 synchronizes time using other standard or customized protocols.

With NTP, computing device 308 acts as a server and speakers 302, 304 as clients. Through the transmission and receipt of data packets, computing device 308 determines the amount time it takes to get a response from each speaker 302, 304. From this information computing device 308 calculates the time delay and offset for each speaker 302, 304. Computing device 308 uses the offsets to adjust clocks 510, 514 to clock 506. Computing device 308 also monitors and maintains the clock of each speaker 302, 304 after the offsets are initially determined.

FIGS. 6A-6B illustrate a flowchart of a method for automatically equalizing multiple loudspeakers in an embodiment in accordance with the invention. Initially a user points a measurement device towards a speaker, as shown at block 600. As described earlier, the measurement device is located at a listening position when positioned towards the speaker.

A computing device then generates an audio signal and known audio pattern and transmits the signal and pattern to the selected speaker (block 602). In one embodiment in accordance with the invention, the known pattern is a Maximum-Length Sequence (MLS) pattern. In other embodiments in accordance with the invention, the audio pattern may be configured as any audio pattern that can be used to measure the acoustics of a room.

The measurement device captures the sound emitted from the speaker and transmits the captured sound to the computing device (blocks 604, 606). The computing device then obtains the characteristics of the speaker and the measurement device, as shown in block 608. In one embodiment in accordance with the invention, the speakers and measurement device are measured and calibrated in a standard environment. This may occur, for example, during manufacturing. The characteristics for the speaker are stored in the speaker and the characteristics for the measurement device are stored in the device. These characteristics are then subsequently obtained by the computing device and used during equalization of the room.

The computing device determines the impulse and frequency responses of the speaker and stores the responses in the computing device, as shown in blocks 610, 612, 614, respectively. A determination is then made at block 616 as to whether there is another speaker in the room that is associated with the current listening position. If so, the process returns to block 600 and repeats until all of the speakers in a room that correspond to the listening position have been measured.

If there is not another speaker associated with the current listening position, the process continues at block 618 where the room is equalized using the frequency and impulse responses for all of the speakers in the room that are associated with the current listening position. A determination is then made at block 620 as to whether the user wants to equalize the room for another listening position. If so, the process returns to block 600 and repeats until the room has been equalized for all of the listening positions.

A determination is then made at block 622 as to whether the room has been equalized for more than one listening position. For example, in the embodiment shown in FIG. 4, a user equalizes the room for two listening positions 310, 402. If the room has been equalized for only one listening position, the process ends.

If however, the room has been equalized for two or more listening positions, a determination is made at block 624 as to whether the user would like to average the compensation and offset values for the multiple listening positions. If the user does want to average the values, an average is generated and stored, as shown in block 626. A determination is then made at block 628 as to whether the user wants to use the average of the offset values for all of the listening positions in the room. If so, the process ends.

If the user does not want to use the average for all of the listening positions in the room, the user selects which listening positions use the average values, as shown in block 630. Selection of the listening positions may occur, for example, through a user interface on the computing device or on a remote device associated with the computing device. The selected listening positions are then stored in the computing device (632).

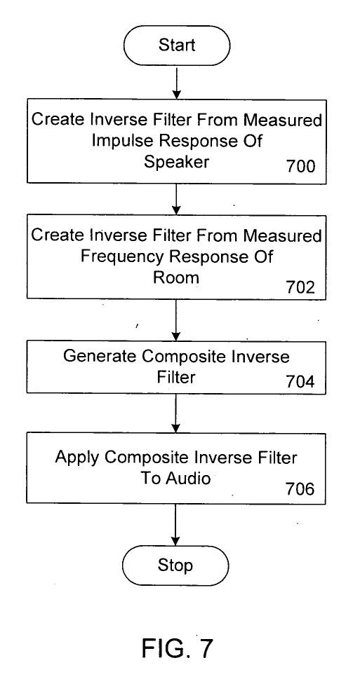

Referring to FIG. 7, there is shown a flowchart of a method for applying an offset for the frequency response of a loudspeaker in an embodiment in accordance with the invention. Initially an inverse filter is created from the measured impulse response of the loudspeaker, as shown in block 700. Another inverse filter is then created at block 702 using the measured frequency response of the room.

A composite inverse filter is then created from the impulse response inverse filter and the frequency response inverse filter (block 704). Next, at block 706, the composite inverse filter is applied to the audio signal. Depending on the magnitude of the nulls and modes of the speaker, some or all of the nulls and modes are eliminated or reduced by applying the composite inverse filter to the audio signal.

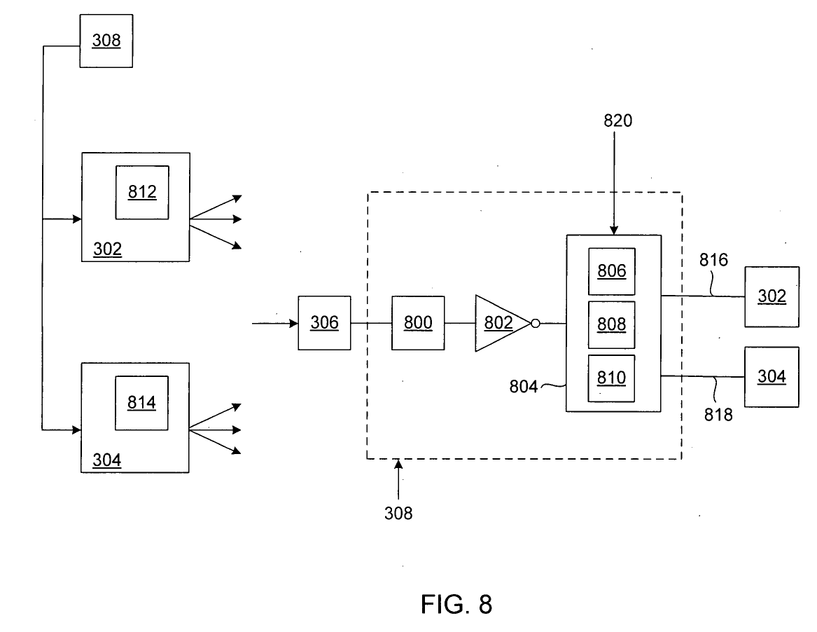

FIG. 8 is a block diagram of a system for applying an offset for the frequency response in accordance with FIG. 7. When a user measures the room (i.e., measurement mode), the computing device 308 generates an audio signal that includes a known pattern. The audio signal and known pattern are transmitted to loudspeakers 302, 304. Speakers 302, 304 then emit the audio signal and known pattern into the room. Measuring device 306 sequentially measures the signal and pattern emitted from each speaker and transmits each captured signal to transfer function 800.

Transfer function 800 generates a difference signal by subtracting the audio signal and pattern output from computing device 308 from, the audio signal and pattern captured by measuring device 306. The difference signal is then input into inverter 802, which inverts the signal. The inverted signal is then input into filter circuit 804.

Filter circuit 804 includes three Finite Impulse Response (FIR) filters 806, 808, 810 in the embodiment of FIG. 8. Filter circuit 804 may be implemented with other types of filters in other embodiments in accordance with the invention. For example, filter circuit 802 may be implemented with one or more Butterworth filters, Bi-quad filters, or a combination of filter types.

FIR filter 806 corresponds to the inverted signal output from inverter 802. FIR filters 808, 810 are associated with audio drivers 812, 814 in loudspeakers 302, 304. Drivers 812, 814 may be implemented, for example, as a woofer and tweeter, respectively. FIR filters 808, 810 blend the equalization curves for drivers 812, 814 to construct the crossover for drivers 812, 814. Combined, FIR filters 806, 808, 810 blend speakers 302, 304 with each other and with the room.

The output from filter circuit 804 is then transmitted to speakers 302, 304 via connections 816, 818, respectively. Connection 816 corresponds to driver 812 and connection 818 to driver 814. The number of drivers, and therefore the number of outputs from filter circuit 804, can include any number of drivers in other embodiments in accordance with the invention. The drivers may be implemented as any audio driver, such as woofers, tweeters, and sub-woofers.

When a user listens to audio data (i.e., playback mode), the audio signal is input into filter circuit 804 via line 820. The audio signal is processed by filter circuit 804, which includes compensating for the frequency responses of the speakers. The processed audio signal is then output to loudspeakers 302, 304.

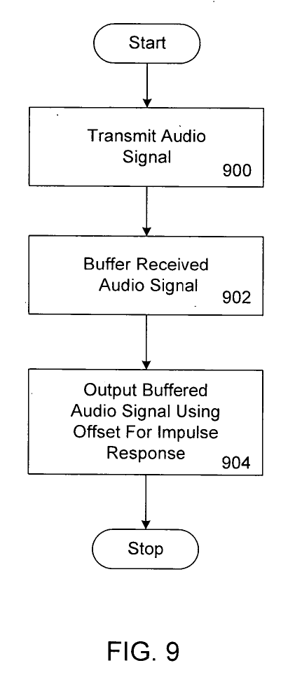

Referring now to FIG. 9, there is shown a flowchart of a method for applying an offset for the impulse response of a loudspeaker in an embodiment in accordance with the invention. A computing device transmits an audio signal to a loudspeaker, as shown in block 900. The audio signal is then buffered in the speaker (block 902). When the timestamp associated with the buffered audio signal correlates with the appropriate time to present the audio signal, the buffered audio signal is emitted from the speaker. As discussed in conjunction with FIG. 5, the speakers are synchronized to a global time, which in the embodiment of FIG. 5 is the clock in the computing device. Thus, the appropriate time to present the audio signal is based on the global time and the time offset for the speaker.

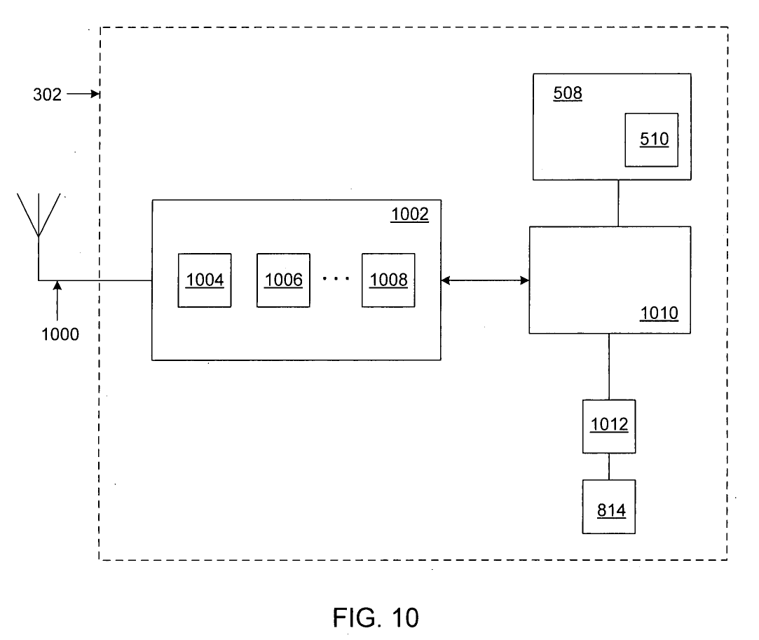

FIG. 10 is a block diagram of a loudspeaker for applying an offset for the impulse response in accordance with FIG. 9. Loudspeaker 302 receives an audio signal via antenna 1000. In one embodiment in accordance with the invention, the audio signal is transmitted over a wireless connection, such as, for example, an IEEE 802.11 connection. In other embodiments in accordance with the invention, the audio signal may be transmitted over a different type of wireless connection or over a wired connection.

The audio signal is input into audio receiver 1002, which includes buffers 1004, 1006, 1008. Audio receiver is implemented as a digital radio in one embodiment in accordance with the invention. The size of buffers is dynamic in one embodiment in accordance with the invention, such that the amount of buffering capacity is determined by the amount of delay needed by the speakers.

Buffers 1004, 1006, 1008 buffer the audio signal until clock 510 in network system 508 indicates the appropriate time to present the buffered audio signal to audio subsystem 1010. As discussed earlier, clock 510 is synchronized to the clock in the computing device. Thus, the appropriate time to present the audio signal is determined by clock 510 and the offset that compensates for the impulse response of speaker 302. When the audio data is presented to audio subsystem 1010, the audio signal is transmitted to amplifier 1012 and driver 1014. Driver 1014 may be implemented, for example, as a woofer. Driver 1014 emits the audio data from speaker 302.

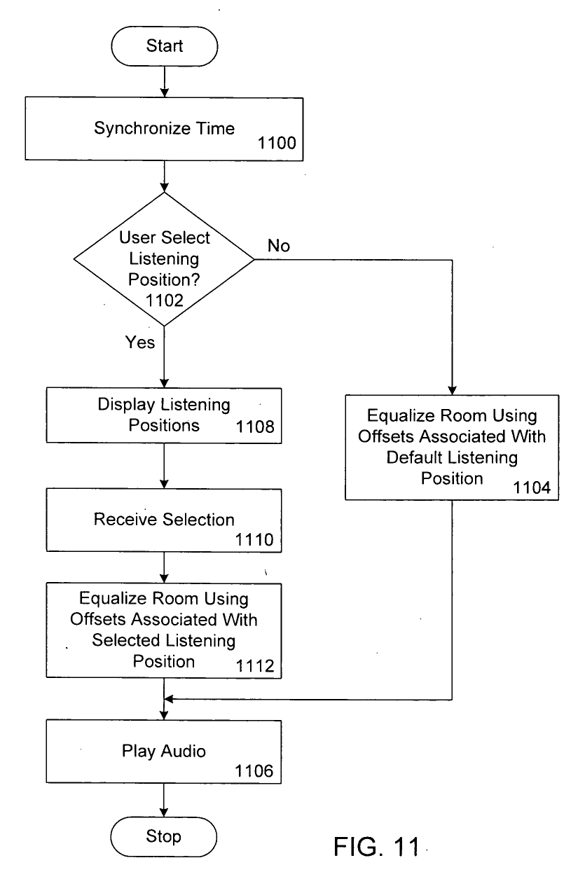

Referring now to FIG. 11, there is shown a flowchart of a method for audio playback in an embodiment in accordance with the invention. When a user is going to listen to audio data, the computing device synchronizes the time for all of the speakers associated with the computing device, as shown in block 1100. The time may, for example, be synchronized according to the embodiment of FIG. 5.

A determination is then made at block 1102 as to whether the user has measured a room for more than one listening position. If not, the process passes to block 1104 where the room is equalized using the offsets associated with a default listening position. The default listening position may be determined by a user or by the system. For example, in one embodiment in accordance with the invention the default position may be the last positioned selected or used by the user. In another embodiment in accordance with the invention, the default position may be the most frequently used listening position. And in yet another embodiment in accordance with the invention, the default position may be an average of two or more listening positions, or it may be a preferred listening position as selected by the user. After the room is equalized for the default listening position, the audio is played at block 1106.

If the user has measured a room for more than one listening position, the method continues at block 1108 where the listening positions are displayed to the user. The user selects a listening position and the computing device receives the selection, as shown in block 1110. The room is then equalized using the compensation or offset values associated with the selected listening position and the audio signal reproduced (block 1112, 1114).

Although the invention has been described with reference to two loudspeakers, embodiments in accordance with the invention are not limited to this implementation. Any number of speakers may be used in other embodiments in accordance with the invention. The speakers may be located in one room or in multiple rooms. Additionally, the speakers may include any number of audio drivers, such as woofers, tweeters, and sub-woofers.

1. A system, comprising:
a computing device; and
multiple speakers connected to the computing device, wherein the computing device automatically equalizes the multiple speakers.

2. The system of claim 1, further comprising a measuring device for capturing a signal emitted from each speaker and transmitting each captured signal to the computing device.

3. The system of claim 1, wherein the computing device automatically equalizes the room by determining a frequency response and an impulse response for each speaker in the room.

4. The system of claim 1, wherein the multiple speakers are connected to the computing device by a wireless connection.

5. The system of claim 1, wherein the computing device is implemented within one of the multiple speakers.

6. The system of claim 1, wherein the computing device is implemented externally from the multiple speakers.

7. A loudspeaker, comprising:
one or more buffers for storing an audio signal;
a network system including a clock; and
an audio system for receiving at least a portion of the audio signal stored in the one or more buffers based on the timing of the clock in the network system.

8. The loudspeaker of claim 7, further comprising:
an amplifier for receiving the audio signal from the audio system; and
an audio driver for receiving the audio signal from the amplifier and for emitting the audio signal out of the loudspeaker.

9. The loudspeaker of claim 8, wherein the audio driver comprises at least one of a woofer, a tweeter, and a sub-woofer.

10. The loudspeaker of claim 7, further comprising an audio receiver for receiving the audio signal over a wireless connection.

11. The loudspeaker of claim 10, wherein the one or more buffers are implemented in the audio receiver.

12. A method for automatically equalizing a plurality of speakers, comprising:
a) emitting from one the plurality of speakers an audio signal including a pattern;
b) capturing the reproduced audio signal including the pattern; and
c) determining a frequency response and an impulse response for the speaker.

13. The method of claim 12, further comprising generating the audio signal including a pattern.

14. The method of claim 12, further comprising repeating a) through c) for all of the speakers in the plurality of speakers.

15. The method of claim. 14, wherein the plurality of speakers are associated with a first listening position.

16. The method of claim 15, further comprising equalizing the plurality of speakers associated with the first listening position.

17. The method of claim 15, further comprising repeating a) through c) for a second listening position.

18. The method of claim 17, further comprising calculating an average of the impulse and frequency responses for the plurality of speakers associated with the first and second listening positions.

19. The method of claim 18, further comprising equalizing the plurality of speakers associated with the first and second listening positions using the average.

20. The method of claim 17, further comprising:
selecting a listening position from the first and second listening positions; and
equalizing the plurality of speakers associated with the selected listening position.
